(19) United States
(12) Patent Application Publication
(10) Pub. No.: US 2025/0203906 A1
(43) Pub. Date: Jun. 19, 2025

(54) SILICON GERMANIUM NANOSHEET TRANSISTOR

(71) Applicant: International Business Machines Corporation, Armonk, NY (US)

(72) Inventors: Sushant Kumar, East Greenbush, NY (US); Ruilong Xie, Niskayuna, NY (US); Shogo Mochizuki, Mechanicville, NY (US); Jianwei Peng, Clifton Park, NY (US)

(21) Appl. No.: 18/541,628

(22) Filed: Dec. 15, 2023

(51) Int. Cl. H01L 29/775; H01L 29/06; H01L 29/66; H01L 29/786

(52) U.S. Cl. CPC H10D 30/43; H10D 30/014; H10D 30/6757; H10D 62/121; H10D 64/017; H10D 64/018

(57) ABSTRACT

A gate all around transistor having reduced bandgap offset between source/drain and channel is provided. The reduced offset can be achieved by one or more of the following features: the source/drain region extending under a portion of an inner spacer, the channel layer extending under a portion of the inner spacer, and a germanium containing portion of the channel layer can be in direct contact with the source/drain material.

### BACKGROUND

The present invention relates generally to the electrical, electronic and computer arts and, more particularly, to the fabrication of integrated circuits.

Gate all around (GAA) nanosheet transistors include a plurality of vertically spaced-apart sheets of channel layers separated from each other by inner spacers. A gate structure for the device is positioned around each of these spaced-apart channel layers. Source/drain material contacts the channel layers outside the gate/inner spacers. GAA transistors have superior gate control and higher short channel effect (“SCE”) suppression ability than fin-type field effects transistors (FinFETs) due to the gate surrounding the channels. GAA nanosheet transistors also provide higher “ON” current and improved electrostatic control over FinFETs. Cladding a silicon germanium (SiGe) epitaxial film over a silicon channel can improve PFET mobility, unfortunately, even if channel mobility is improved, band gap offsets between the channel layer and source/drain can limit performance.

### BRIEF SUMMARY

Principles of the invention provide techniques for silicon germanium nanosheet transistors; for example, providing various channel geometries in GAA nanosheet transistors that allow for fine tuning of operational characteristics. In one aspect, an exemplary semiconductor structure includes a gate all around transistor including a gate having opposing sides; a gate spacer on the opposing sides of the gate; one or more inner spacers below and vertically aligned with the gate spacers; a source/drain material on either side of the gate and extending under the inner spacers; and a channel layer under the gate, extending under the inner spacer and in contact with the source/drain material.

In another aspect, an exemplary a gate all around transistor includes a gate having opposing sides; a gate spacer on the opposing sides of the gate; an inner spacer below and vertically aligned with the gate spacers; a source/drain material on either side of the gate; a cladded channel layer under the gate, extending under the inner spacer wherein a cladding material of the cladded channel is in contact with the source/drain material.

In still a further aspect, an exemplary method of forming a transistor includes providing a substrate; forming a nanostack on the substrate wherein the nanostack comprises alternating layers of a sacrificial layer and a channel layer; etching the nanostack to form an active area fin; forming a dummy gate over and perpendicular to the fin; etching the fin using the dummy gate as a mask to expose outer edges of the sacrificial layer and the channel layer; recessing the outer edges of the sacrificial layer to form a spacer cavity; forming inner spacers in the spacer cavity; recessing the outer edges of the channel layer to form an extension cavity under the inner spacers; forming source/drain material on the substrate and in the extension cavity; removing the sacrificial layer and dummy gate to form a gate cavity; trimming the channel layer exposed by the gate cavity; cladding the channel layer with silicon germanium to form a cladded channel portion; and forming a replacement metal gate structure in the gate cavity.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1A-C depict a top-down layout, cross-section along the X-axis, and cross-section along the Y-axis, respectively, of an exemplary starting point in making a transistor according to aspects of the invention;

FIGS. 2A-2C illustrate the structure of FIGS. 1A-1C after forming a nanostack active area fin and shallow trench isolation regions according to aspects of the invention;

FIGS. 3A-3C illustrate the structure of FIGS. 2A-2C after forming a dummy gate according to aspects of the invention;

FIGS. 4A-4C illustrate the structure of FIGS. 3A-3C after etching the fin using the dummy gate as a mask according to aspects of the invention;

FIGS. 5A-5C illustrate the structure of FIGS. 4A-4C after recessing the sacrificial layer according to aspects of the invention;

FIGS. 6A-6C illustrate the structure of FIGS. 5A-5C after forming inner spacers according to aspects of the invention;

FIGS. 7A-7C illustrate the structure of FIGS. 6A-6C after recessing the channel layer according to aspects of the invention;

FIGS. 8A-8C illustrate the structure of FIGS. 7A-7C after forming source/drains according to aspects of the invention;

FIGS. 9A-9C illustrate the structure of FIGS. 8A-8C after removing the dummy gate according to aspects of the invention;

FIGS. 10A-10C illustrate the structure of FIGS. 9A-9C after trimming the channel layer according to aspects of the invention;

FIGS. 11A-11C illustrate the structure of FIGS. 10A-10C after cladding the channel layer according to aspects of the invention;

FIGS. 12A-12C illustrate the structure of FIGS. 11A-11C after forming a replacement metal gate structure according to aspects of the invention; and

FIGS. 13A-13C illustrate the structure of FIGS. 12A-12C after forming contacts according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

In summary (reference characters refer to the drawings discussed below), aspects of the invention can include a gate all around transistor including a gate 1200 having opposing sides 1200-S; a gate spacer 320 on the opposing sides 1200-S of the gate 1200; one or more inner spacers 600 below and vertically aligned with the gate spacers 320; a source/drain material 800 on either side of the gate 1200 and extending under the inner spacers 600; and a channel layer 114 under the gate 1200, extending under the inner spacer 600 and in contact with the source/drain material 800. The channel layer having a first germanium concentration and the source/drain material having a second germanium concentration. The technical benefit of which is the reduction or elimination of the bandgap offset between the source/drain and the channel layer of a PFET which decreases the potential barrier thereby reducing junction resistance at the source/drain and channel. In addition, the hole mobility is increased, resulting in the PFET performance approaching that of NFETs. In addition, there is improved by improved threshold voltage modulation and improved negative biased temperature instability (NBTI).

Optionally, the source/drain has 20% to 70% germanium. The technical benefits are as noted prior with the additional benefit of use of material that can be readily used in manufacturing.

Optionally, the first geranium concentration can be less than the second germanium concentration. The technical benefits are as noted prior with the additional benefit of use of material that can be readily used in manufacturing.

Optionally, the first germanium concentration can be equal to or less than 75% of the second geranium concentration. The technical benefits are as noted prior with the additional benefit of use of material that can be readily used in manufacturing.

Optionally, the channel layer 114 can comprise a core material 1120 of silicon and a silicon germanium cladding 1100 layer. The technical benefit is the use of materials that can be readily used in manufacturing.

Optionally, the cladding 1100 layer can, advantageously, be in direct contact with the source/drain material 800. The technical benefit of which is the reduction or elimination of the bandgap offset between the source/drain and the channel layer of a PFET which decreases the potential barrier thereby reducing junction resistance at the source/drain and channel. In addition, the hole mobility is increased, resulting in the PFET performance approaching that of NFETs. In addition, there is improved by improved threshold voltage modulation and improved negative biased temperature instability (NBTI).

Furthermore, the transistor's the inner spacer 600 has a length 600-L. Optionally, the source/drain material 800 can extend under the inner spacer 600 by a distance less than or equal to half of the inner spacer length 600-L. The extension of the source/drain material 800 facilitates contact with the cladding 1100 layer which enables the prior listed benefits.

Optionally, the gate 1200 can extend under the inner spacer 600. The technical benefit is additional gate control surface.

Optionally, the gate 1200 can extend under the inner spacer 600 by a distance less than or equal to half of the inner spacer length 600-L. The technical benefit is additional gate control surface.

Optionally, the in other aspect, gate 1200 can extend under the inner spacer 600 by more than half of the inner spacer length 600-L. The technical benefit is additional gate control surface.

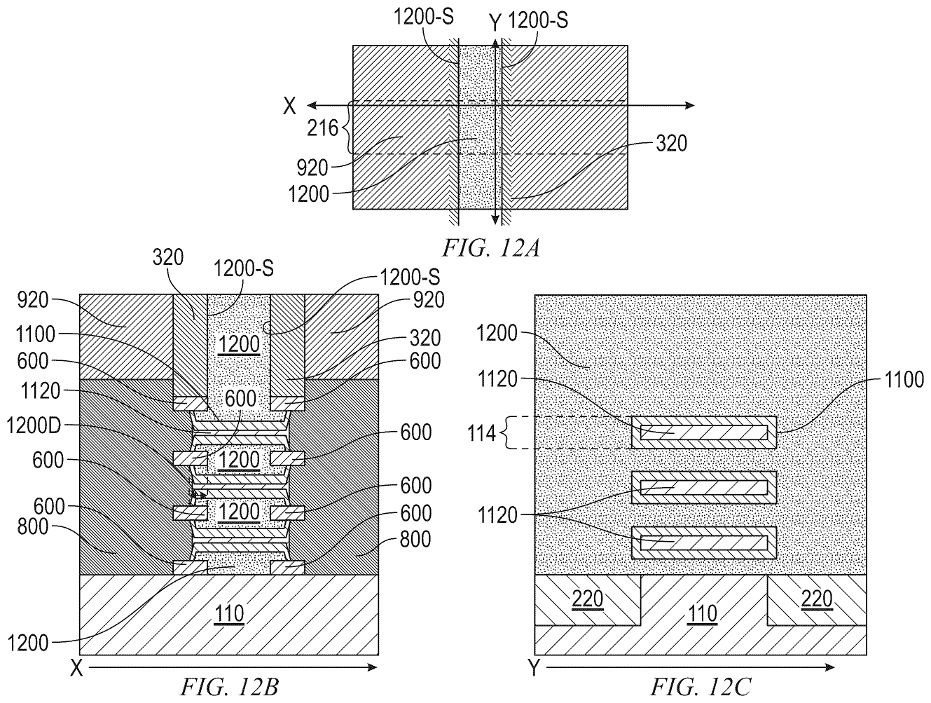

In summary and referring to FIG. 12B, another aspect includes a gate all around transistor having a gate 1200 having opposing sides 1200-S; a gate spacer 320 on the opposing sides 1200-S of the gate 1200; an inner spacer 600 below and vertically aligned with the gate spacers 320; a source/drain material 800 on either side of the gate 1200; a cladded channel layer 114 under the gate 1200, extending under the inner spacer 600 wherein a cladding 1100 material of the cladded channel layer 114 is in contact with the source/drain material 800. The source/drain material 800 and the cladding 1100 material comprise silicon germanium. The technical benefit of which is the reduction or elimination of the bandgap offset between the source/drain and the channel layer of a PFET which decreases the potential barrier thereby reducing junction resistance at the source/drain and channel. In addition, the hole mobility is increased, resulting in the PFET performance approaching that of NFETs. In addition, there is improved by improved threshold voltage modulation and improved negative biased temperature instability (NBTI).

Optionally, the source/drain material has a second germanium concentration, and the cladding material has a first germanium concentration. Please see prior paragraph for technical benefits.

Optionally the second germanium concentration is in the range of 20% to 70% Ge. In addition to the prior performance benefits, the concentration range is compatible with manufacturing.

Optionally, the first germanium concentration is in the range of 15% to 50% Ge. In addition to the prior performance benefits, the concentration range is compatible with manufacturing.

Optionally, the transistor can include a core material 1120 of the clad channel layer 114 in which the core material 1120 includes silicon. In addition to the prior performance benefits, the concentration range is compatible with manufacturing.

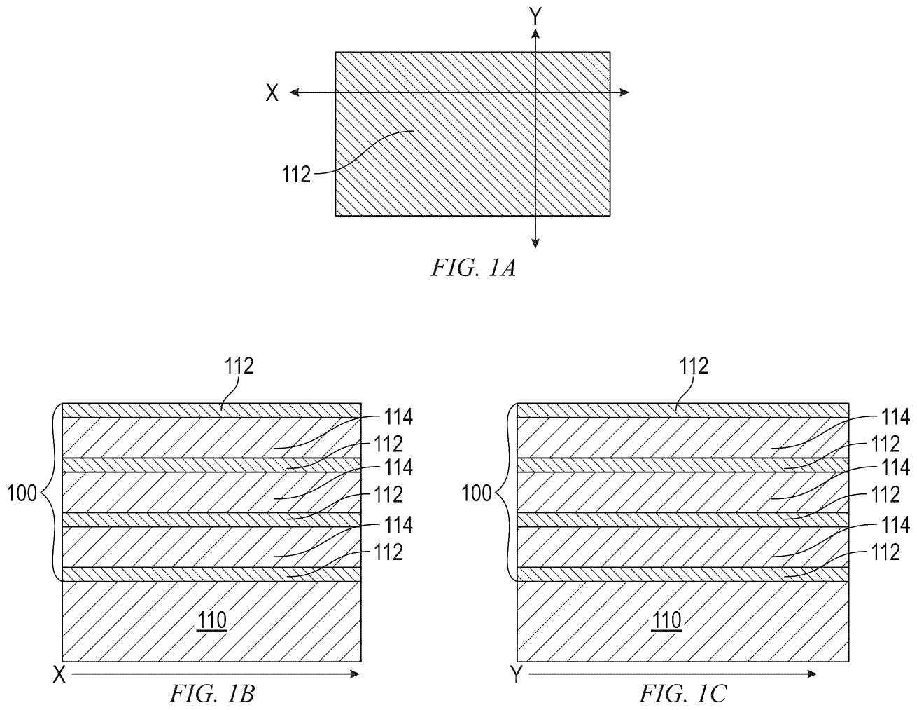

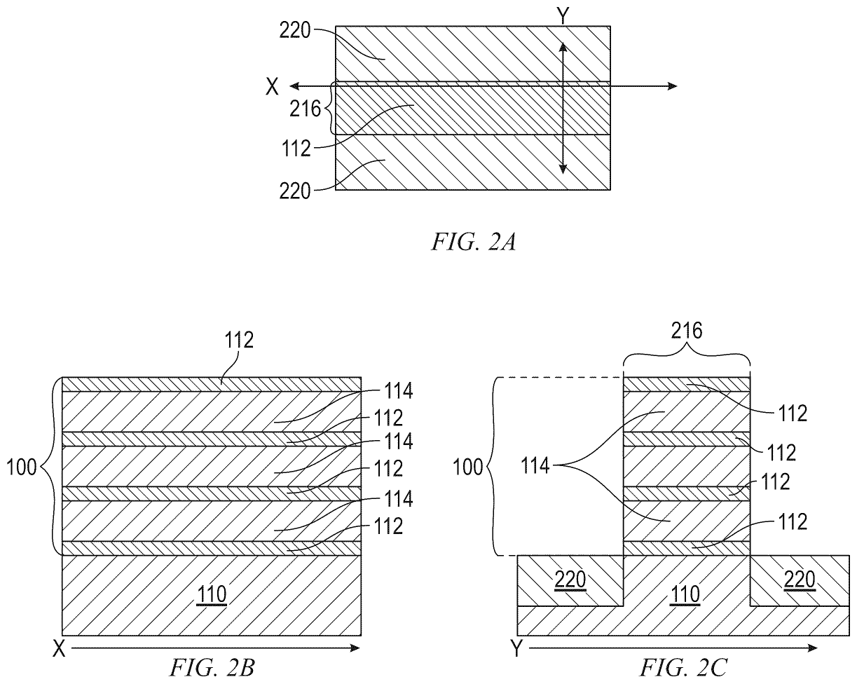

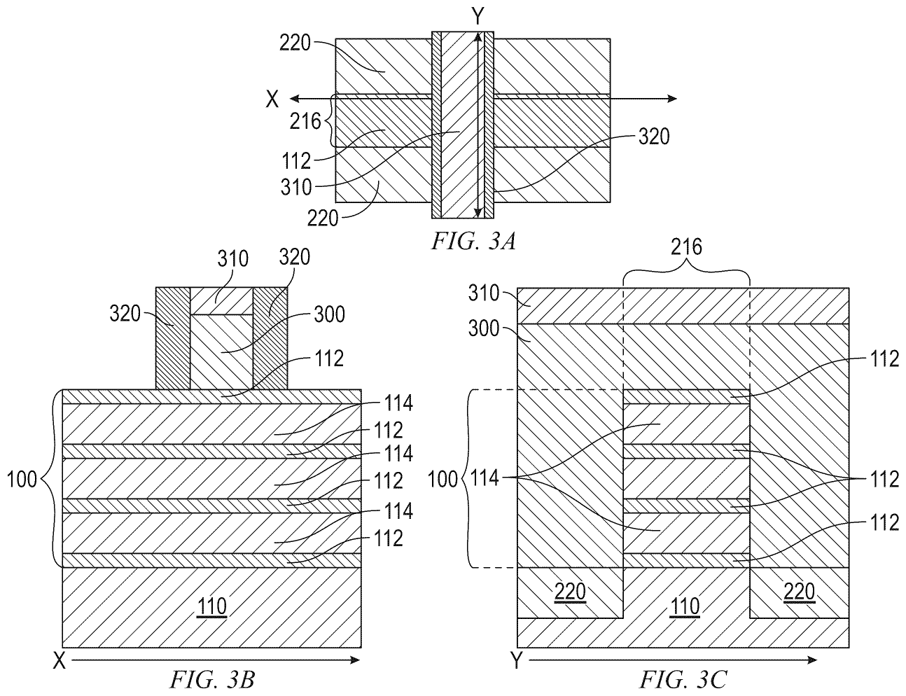

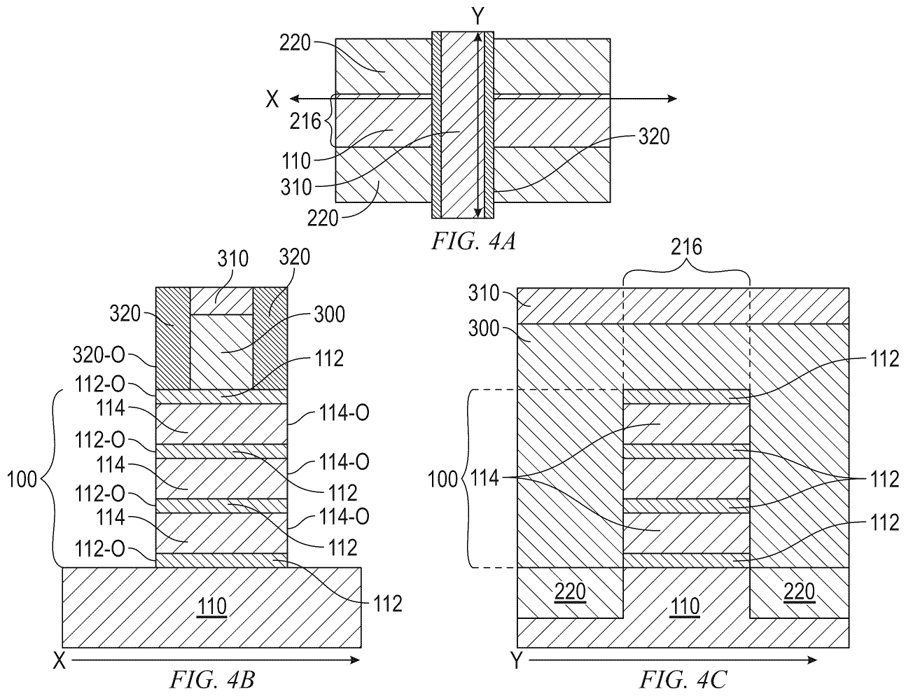

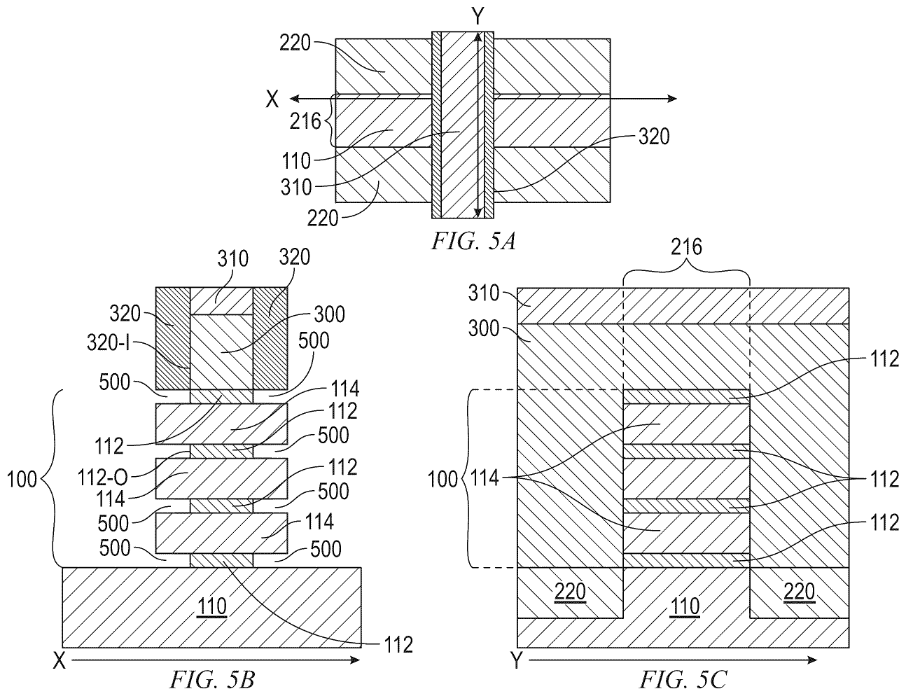

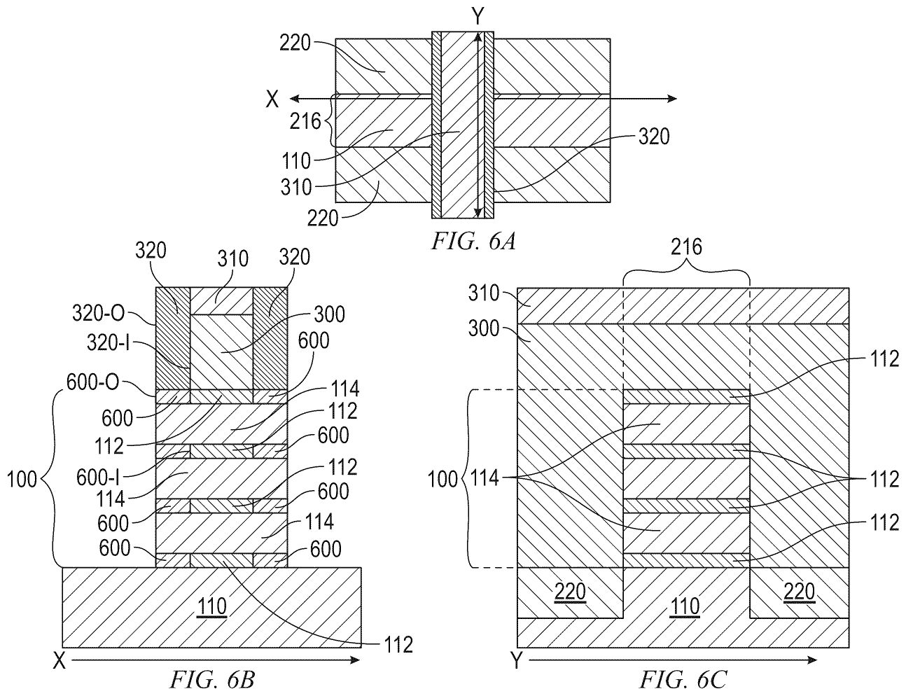

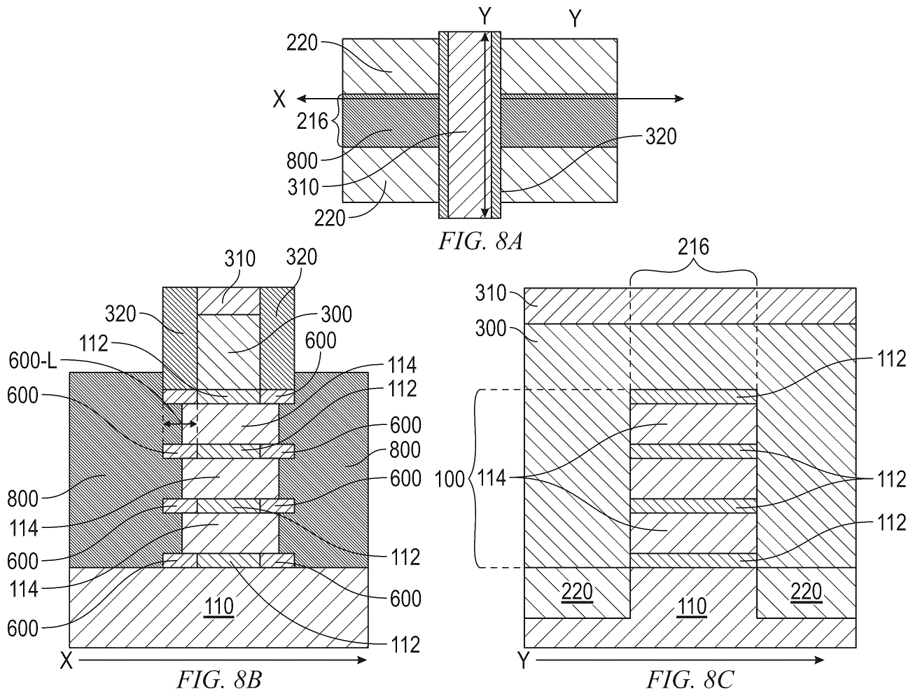

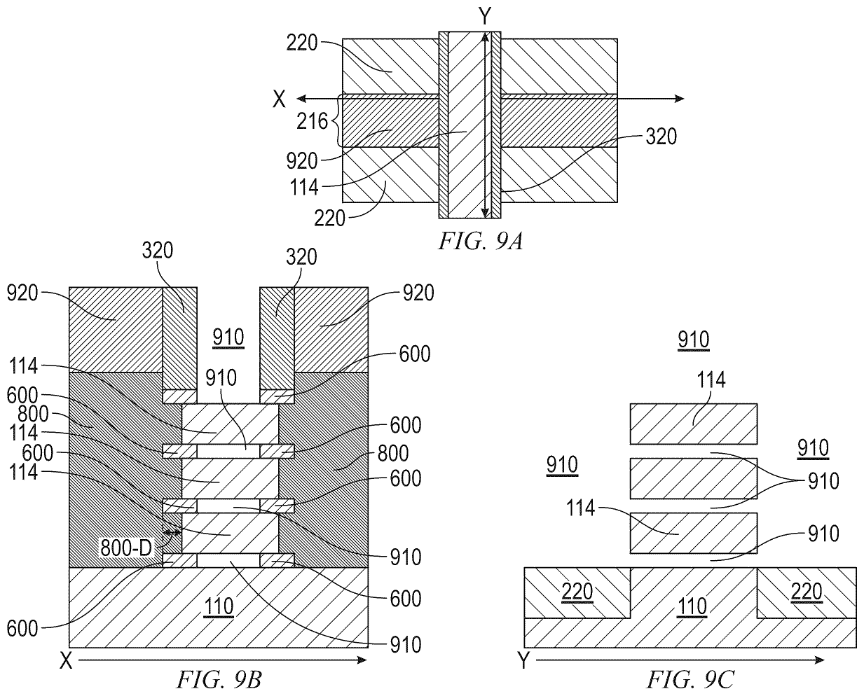

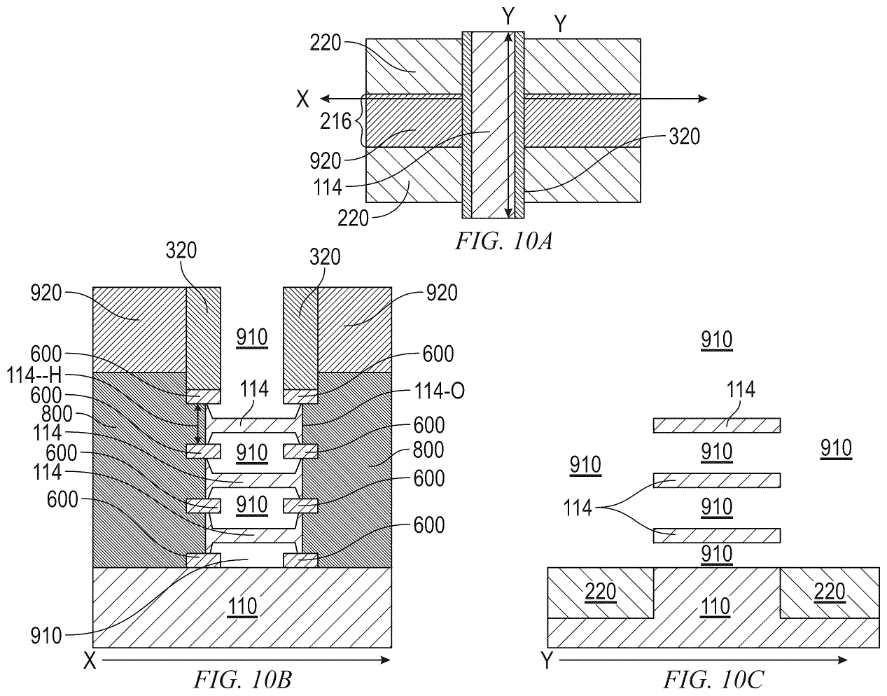

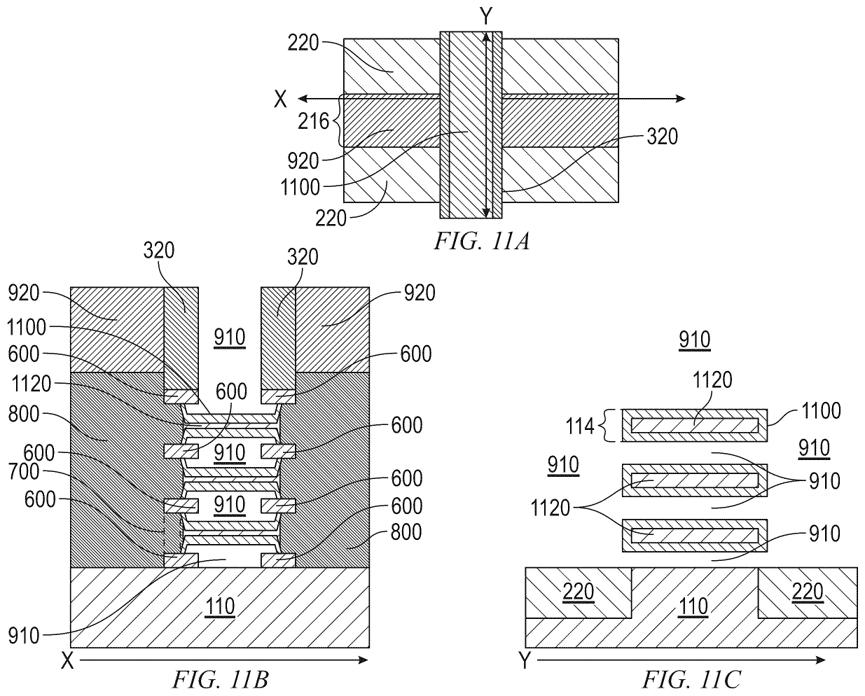

In summary, an aspect of making a transistor includes providing a substrate 110; forming a nanostack 100 on the substrate 110 wherein the nanostack 100 comprises alternating layers of a sacrificial layer 112 and a channel layer 114 (see FIG. 1B); etching the nanostack 100 to form an active area fin 216; (see FIGS. 2A and 2C); forming a dummy gate 300 over and perpendicular to the fin 216 (see FIGS. 3A and 3B); etching the fin 216 using the dummy gate 300 as a mask to expose outer edges of the sacrificial layer 112-O and the channel layer 114-O (see FIG. 4B); recessing the outer edges of the sacrificial layer 112-O to form a spacer cavity 500; (see FIG. 5B); forming inner spacers 600 in the spacer cavity 500 (see FIG. 6B); recessing the outer edges of the channel layer 114-O to form an extension cavity 700 under the inner spacers 600; forming source/drain material 800 on the substrate 110 and in the extension cavity 700 (see FIG. 8B); removing the sacrificial layer 112 and dummy gate 300 to form a gate cavity 910 (see FIG. 9B); trimming the channel layer 114 exposed by the gate cavity 910 (FIG. 10B); cladding 1100 the channel layer 114 with silicon germanium to form a cladded channel portion (see FIG. 11B); and forming a replacement metal gate 1200 structure in the gate cavity 910 (see FIG. 12B). The cladding 1100 of the channel layer 114, advantageously, can be in direct contact with the source/drain material 800 in the extension cavity 700 (see FIG. 12B). The technical benefit is the creation of a transistor which has reduced bandgap offset between the source/drain and the channel layer of a PFET which advantageously decreases the potential barrier thereby reducing junction resistance at the source/drain and channel. In addition, the hole mobility is increased, resulting in the PFET performance approaching that of NFETs. In addition, there is improved by improved threshold voltage modulation and improved negative biased temperature instability (NBTI).

Optionally, a germanium concentration of the cladded channel portion is less than a second germanium concentration of the source/drain material. In addition to the prior benefits, the different concentrations can aid in manufacturability.

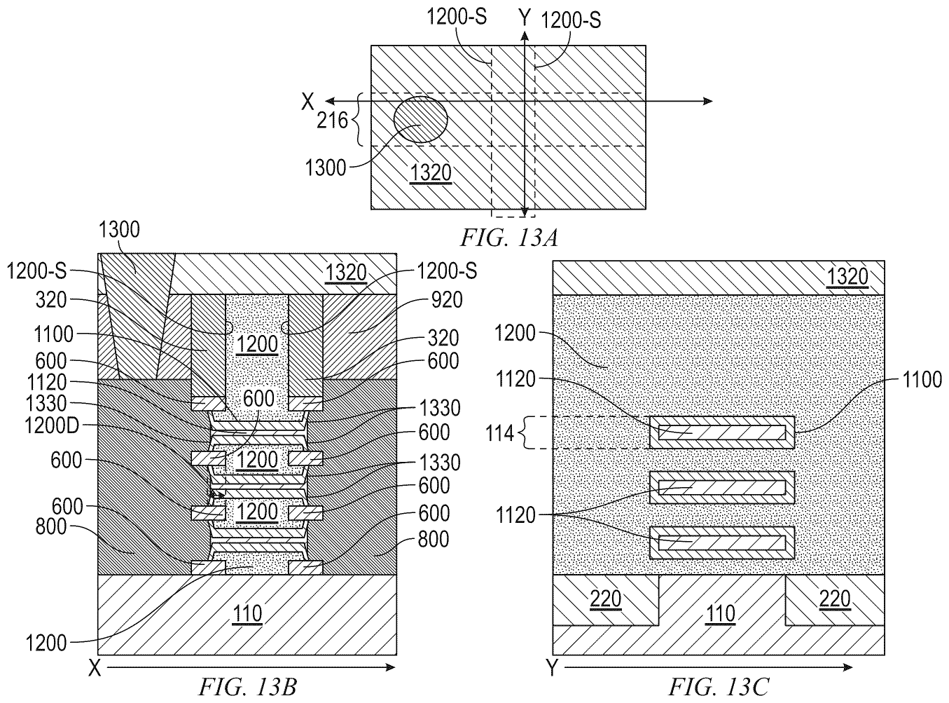

Optionally, the method can further include forming contacts 1300 to the source/drain material 800 (see FIG. 13B). In addition to the prior benefits, the contact formation is compatible with transistor formation.

Optionally, the method can include forming a portion of the metal gate 1200 structure under the inner spacer 600 (see FIG. 12B). The technical benefit is additional gate control surface.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:

Allow further scaling, enhanced yield, and/or enhanced reliability for semiconductor structures using GAA nanosheet transistors:
by reducing or eliminating the bandgap offset between the source/drain and the channel layer of a PFET which decreases the potential barrier thereby reducing junction resistance at the source/drain and channel
by increasing the hole mobility so that PFET performance approaches that of NFETs
by improved threshold voltage modulation
by improved negative biased temperature instability (NBTI).

Aspects of invention provide techniques for recessing, trimming, and cladding channel material in a GAA nanosheet transistor for performance improvement of the transistor; generally, various techniques for forming a gate all around (“GAA”) field effect transistor (“FET”) nanosheet device having minimal band offset are provided. FIGS. 1A-1C depict a starting point in the process for making an improved GAA transistor according to an aspect of the invention. Referring to FIG. 1A, a top-down view of the starting point shows a top layer which can be a sacrificial layer 112. FIGS. 1B and 1C are cross-sections taken along the X and Y lines, respectively, of FIG. 1A. At this exemplary starting point, FIGS. 1B and 1C look the same; namely, there is a substrate 110 with a nanostack 100 of alternating layers of a sacrificial layer 112 and channel layer 114. Here, three channel layers 114 are present, but there could be fewer or more. Channel layers 114 can be silicon and sacrificial layers 112 can be silicon germanium with a germanium concentration sufficient to be etched selectively with respect to the channel layer 112.

FIGS. 2A-2C depict the structure of FIGS. 1A-1C after the nanostack 100 has gone through a lithography and etch process to form an active area fin 216 on the substrate. In FIG. 2A, the active area fin 216 is formed along the X direction. Referring to FIGS. 2A and 2C, on either side of active area fin 216 are shallow trench isolation regions 220 (“STI”) which can include a silicon-nitride based liner and silicon-oxide based fill material.

FIGS. 3A-3C depict the structure of FIGS. 2A-2C after forming a dummy gate 300, hard mask 310 and gate spacers 320. The dummy gate 300 and hard mask 310 are deposited and then lithographically patterned and etched to run perpendicular to and cross over the active area fin 216 (see FIG. 3A). After patterning, the gate spacers 320 are formed around the dummy gate 300 (see FIGS. 3A and 3B). The dummy gate can be amorphous silicon. The hard mask 310 can be silicon-nitride based, or combination of SiO₂ and SiN. The gate spacers 320 can be silicon nitride, silicon oxy-carbon (SiOC), or silicon oxy-carbon nitride (SiOCN).

FIGS. 4A-4C depict the structure of FIGS. 3A-3C after etching the nanostack 100 using the dummy gate 300 and gate spacers as a mask. Referring to FIG. 4B, the nanostack 100 is etched to reveal substrate 110. Etching the nanostack 100 exposes outer edges of the channel layer 114-O and outer edges of the sacrificial layer 112-O which can be vertically aligned (within typical process tolerances) with the outer edges 320-O of gate spacers 320.

FIGS. 5A-5C depict the structure of FIGS. 4A-4C after recessing the exposed outer edges of the sacrificial layer 112-O to form spacer cavities 500. Referring to FIG. 5B, the recessing moves the outer edges of the sacrificial layer 112-O inward such that the sacrificial layer outer edges 112-O can be vertically aligned (within typical process tolerances) to the inner edges 320-I of the gate spacer 320.

FIGS. 6A-6C depict the structure of FIGS. 5A-5C after filling the spacer cavities 500 with insulating material resulting in inner spacers 600. Referring to FIG. 6B, outer edges 600-O of the inner spacers 600 can be vertically aligned (within typical process tolerances) to the outer edges 320-O of the gate spacer 320. Similarly, inner edges 600-I of the inner spacer 600 and inner edges 320-I of the gate spacer 320 can be vertically aligned (within typical process tolerances). The inner spacers 600 can be silicon nitride, silicon boron carbon nitride (SiBCN), or silicon oxy-carbon nitride (SiOCN).

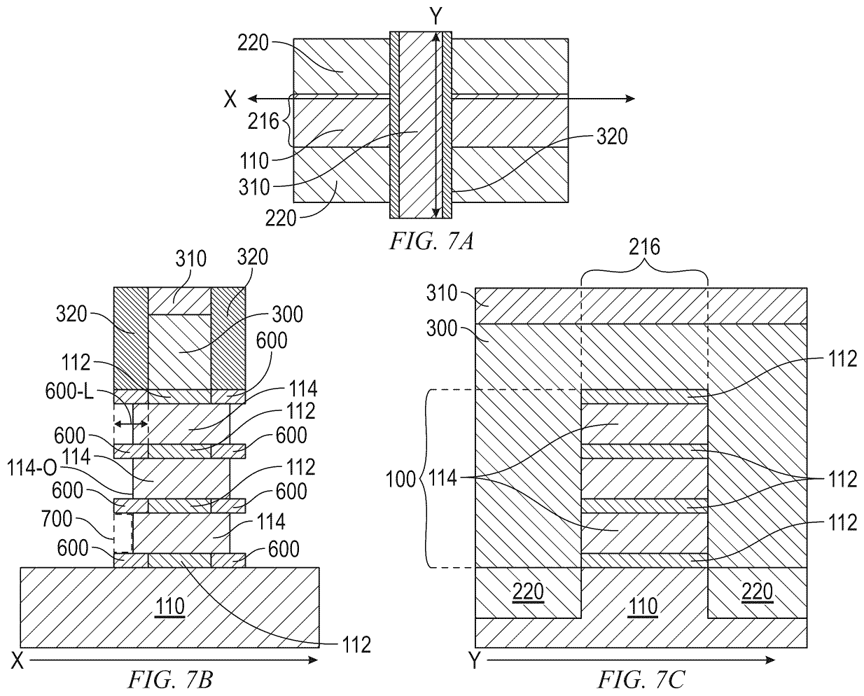

FIGS. 7A-7C depict the structure of FIGS. 6A-6C after recessing the channel layers 114 to from extension cavities 700 (depicted with a dash-dotted box). As a result of recessing, the exposed outer edges 114-O of channel layers 114 are moved inward so that they are vertically under the inner spacers 600 (see FIG. 7B). Also denoted in FIG. 7B, is the length of the inner spacers 600-L spanning the inner spacer outer edge 600-O (see FIG. 6B) to the inner spacer inner edge 600-I (see FIG. 6B).

FIGS. 8A-8C depict the structure of FIGS. 7A-7C after growing source/drain 800 material on the substrate 110 and from the channel layer 114, thereby filling the extension cavity 700. In an advantageous embodiment of a PFET, the source/drain 800 material can be boron doped silicon germanium.

FIGS. 9A-9C, depict the structure of FIGS. 8A-8C after sacrificial layer 112 removal. After the channel layers 114 are in contact and secured by the source/drain 800 material, the sacrificial layers 112 between the channel layers 114 can be removed. Several preparatory steps are employed prior to removing the sacrificial layers 112. First a dielectric layer 920 can be deposited and polished to be co-planar with the gate spacers 320. Next the hard mask 310 and dummy gate 300 may be removed to create gate cavity 910 between the gate spacers 320 and between the channel layers 114. Note that while channel layers 114 may appear to float in FIG. 9C, the channel layers 114 are attached to source/drain 800 material (see FIG. 9B in conjunction with FIG. 9A). Referring to FIG. 9B, the distance 800-D that the source/drain 800 material extends under the inner spacer 900 is shown.

FIGS. 10A-10C depict the structure of FIGS. 9A-9C after trimming the channel layers 114. Referring to FIG. 10B, due to different etch rates of the different crystallographic planes of the channel layer 114, the trimmed channel can achieve a “dog-bone” shape, meaning that the center is thinner than the outer edges 114-O in contact with the source/drain 800 material. The outer edges of the trimmed channel 114-O may have a height 114-H that spans from one inner spacer 600 to a next inner spacer 600 (see FIG. 10B). Alternatively, the height 114-H of the channel outer edge 114-O of the trimmed channel layer 114 may not fully span from one inner spacer 600 to a next inner spacer 600 such that there is an exposed portion of source/drain 800 material under the inner spacer 600.

FIGS. 11A-11C depict the structure of FIGS. 10A-10C after forming a cladding 1100 material on the channel layers 114. Referring to FIG. 11C, after cladding, the channel layer 114 may be composed of cladded portion and a core 1120 portion. Advantageously, the claddeding1100 may be a same or similar (e.g., different doping levels of common elements) material as the source/drain 800. Advantageously in a PFET aspect of the invention, the source/drain material may be silicon germanium having a germanium concentration from about Si_{0.8}Ge_{0.2} to about Si_{0.3}Ge_{0.7} and ranges therebetween, for example 40% to 70% Ge while the cladding 1100 may be silicon germanium having a germanium concentration from about Si_{0.85}Ge_{0.15} to about Si_{0.5}Ge0_{0.5} and ranges therebetween, for example 15% to 35% Ge. The core 1120 can include the remaining original channel layer 114 material (e.g., silicon). Referring to FIG. 11B, the cladding 1100 is in direct contact with the source/drain 800 material; by having such a construction, namely both source/drain 800 material and cladding 1100 being silicon germanium at the junction of the source/drain 800 and channel layer 114 reduces the band gap offset which in turn allows for lower junction resistance. Therefore, in a PFET aspect, the cladding 1100 in direct contact with the source/drain 800 creates a continuous, low band gap path from initial source/drain 800 through silicon germanium cladded channel to the other source/drain 800. The cladding layer 1100 can be in direct contact either (1) because part of the source/drain 800 under the inner spacer 600 became exposed during the channel trimming process, or (2) because the cladding layer 1100 diffused into the core material 1120 thereby converting the core layer 1120 to the cladding material 1100.

FIGS. 12A-12C, depict the structure of FIGS. 11A-11C after forming a replacement metal gate 1200 structure in the gate cavity 910. The gate 1200 has opposing sides 1200-S adjacent the inner surfaces of gate spacers 320. The gate 1200 structure can include one or more of an interfacial layer, gate oxide layer, work function material(s) and metal fill. Referring to FIG. 12B, 1200-D is the distance, in some embodiments, that the gate can extend under the inner spacer 600.

FIGS. 13A-13C depict the structure of FIGS. 12A-12C after forming contact structures. FIGS. 13A and 13B depict an aspect of the invention in which a contact 1300 is made to the source/drain 800 after an additional interlevel dielectric 1320 is formed. While not shown, a similar contact 1300 can be made to RMG 1200. Interlevel dielectric 1320 can be one or more layers of silicon-oxide based, silicon-nitride based, or low-k films with K value<3.9. Referring to FIG. 13B, note that the cladding material 1100 can be in contact with the source/drain 800 material at location 1330.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A gate all around transistor comprising:
a gate having opposing sides;
a gate spacer on the opposing sides of the gate;
one or more inner spacers below and vertically aligned with the gate spacers;
a source/drain material on either side of the gate and extending under the inner spacers; and
a channel layer under the gate, extending under the inner spacer and in contact with the source/drain material;
wherein the channel layer has a first germanium concentration and wherein the source/drain material has a second germanium concentration.

2. The transistor of claim 1 wherein the second germanium concentration is in a range of 20% to 70% germanium.

3. The transistor of claim 2 wherein the first geranium concentration is less than the second germanium concentration.

4. The transistor of claim 2 wherein the first germanium concentration is equal to or less than 75% of the second geranium concentration.

5. The transistor of claim 1 wherein the channel layer comprises a silicon core and a silicon germanium cladding layer.

6. The transistor of claim 5 wherein the cladding layer is in direct contact with the source/drain material.

7. The transistor of claim 1 wherein the inner spacer has a length and wherein the source/drain material extends under the inner spacer by a distance less than or equal to half of the inner spacer length.

8. The transistor of claim 1 wherein the inner spacer has a length and wherein the source/drain material extends under the inner spacer by more than half of the inner spacer length.

9. The transistor of claim 1 wherein the gate extends under the inner spacer.

10. The transistor of claim 9:
wherein the inner spacer has a length and wherein the gate extends under the inner spacer by a distance less than or equal to half of the inner spacer length.

11. The transistor of claim 9 wherein the inner spacer has a length and wherein the gate extends under the inner spacer by more than half of the inner spacer length.

12. A gate all around transistor comprising:
a gate having opposing sides;
a gate spacer on the opposing sides of the gate;
an inner spacer below and vertically aligned with the gate spacers;
a source/drain material on either side of the gate;
a cladded channel layer under the gate, extending under the inner spacer wherein a cladding material of the cladded channel is in contact with the source/drain material; and
wherein the source/drain material and the cladding material comprise silicon germanium.

13. The transistor of claim 12 wherein the source/drain material has a second germanium concentration, and the cladding material has a first germanium concentration.

14. The transistor of claim 13 wherein the second germanium concentration is in the range of 20% to 70% germanium.

15. The transistor of claim 13 wherein the first germanium concentration is in the range of 15% to 50% germanium.

16. The transistor of claim 13 further comprising a core material of the cladded channel layer wherein the core material includes silicon.

17. A method of making a transistor comprising:
providing a substrate;
forming a nanostack on the substrate wherein the nanostack comprises alternating layers of a sacrificial layer and a channel layer;
etching the nanostack to form an active area fin;
forming a dummy gate over and perpendicular to the fin;
etching the fin using the dummy gate as a mask to expose outer edges of the sacrificial layer and the channel layer;
recessing the outer edges of the sacrificial layer to form a spacer cavity;
forming inner spacers in the spacer cavity;
recessing the outer edges of the channel layer to form an extension cavity under the inner spacers;
forming source/drain material on the substrate and in the extension cavity;
removing the sacrificial layer and dummy gate to form a gate cavity;
trimming the channel layer exposed by the gate cavity;
cladding the channel layer with silicon germanium to form a cladded channel portion in direct contact with the source/drain material in the extension cavity; and
forming a replacement metal gate structure in the gate cavity.

18. The method of claim 17, wherein a germanium concentration of the cladded channel portion is less than a second germanium concentration of the source/drain material.

19. The method of claim 17, further comprising forming contacts to the source/drain material 800.

20. The method of claim 17, further comprising forming a portion of the metal gate structure under the inner spacer.
